(19) United States
(12) Patent Application Publication
(10) Pub. No.: US 2024/0258936 A1
(43) Pub. Date: Aug. 1, 2024

(54) DRIVE ELEMENT

(71) Applicant: Panasonic Intellectual Property Management Co., Ltd., Osaka (JP)

(72) Inventor: Takami ISHIDA, Osaka (JP)

(21) Appl. No.: 18/630,476

(22) Filed: Apr. 9, 2024

Related U.S. Application Data
(63) Continuation of application No. PCT/JP2022/035781, filed on Sep. 26, 2022.

(30) Foreign Application Priority Data
Oct. 13, 2021 (JP) 2021-167880

(51) Int. Cl. H02N 2/00; G02B 26/08; H02N 2/10

(52) U.S. Cl. CPC H02N 2/0085; G02B 26/0858; H02N 2/108

(57) ABSTRACT

A drive element is a drive element for rotating a movable part about a rotation axis, the drive element including: a fixation part rotatably supporting the movable part; and a drive part configured to rotate the movable part, wherein the drive part includes a piezoelectric layer, an upper electrode and a lower electrode placed with the piezoelectric layer interposed therebetween, and an insulating layer covering the piezoelectric layer, the upper electrode, and the lower electrode, and a wiring part composed of a single conductive layer connected to the upper electrode via a contact hole formed in the insulating layer is installed up to the fixation part.

### CROSS REFERENCE TO RELATED APPLICATION

This application is a continuation of International Application No. PCT/JP2022/035781 filed on Sep. 26, 2022, entitled “DRIVE ELEMENT”, which claims priority under 35 U.S.C. Section 119 of Japanese Patent Application No. 2021-167880 filed on Oct. 13, 2021, entitled “DRIVE ELEMENT”. The disclosures of the above applications are incorporated herein by reference.

### BACKGROUND OF THE INVENTION

### Field of the Invention

The present invention relates to a drive element that drives a movable part about a rotation axis.

### Description of Related Art

A drive element that drives a movable part about a rotation axis has been known. In this type of drive element, for example, a mirror is placed on the movable part. Accordingly, scanning can be performed with a beam incident on the mirror as the mirror is driven. That is, in this configuration, the drive element and the mirror constitute a light deflector.

International Publication No. WO2020/045152 describes a tuning-fork-shaped drive element. A piezoelectric element is placed on each of the upper surfaces of two arm parts that are placed so as to be symmetrical with respect to a rotation axis.

In the drive element described above, a voltage for drive is supplied to each piezoelectric element via a wire. The wire is connected to an upper electrode of the corresponding piezoelectric element. In this case, by integrally forming the wire and the piezoelectric element in the same lamination structure as the piezoelectric element, the wire can be smoothly connected to the upper electrode of the piezoelectric element while simplifying the manufacturing process for the drive element.

However, in this configuration, when a voltage is applied to each piezoelectric element via the wire, a driving force is generated by an inverse piezoelectric effect even at the installation position of the wire other than the piezoelectric element. Therefore, unnecessary stress and vibration occur at the installation position of the wire other than the piezoelectric element. This unnecessary stress may cause damage to the drive element, and the unnecessary vibration may deteriorate the characteristics of the drive element.

### SUMMARY OF THE INVENTION

A main aspect of the present invention is directed to a drive element for rotating a movable part about a rotation axis. The drive element according to this aspect includes: a fixation part rotatably supporting the movable part; and a drive part configured to rotate the movable part. The drive part includes a piezoelectric layer, an upper electrode and a lower electrode placed with the piezoelectric layer interposed therebetween, and an insulating layer covering the piezoelectric layer, the upper electrode, and the lower electrode. A wiring part composed of a single conductive layer connected to the upper electrode via a contact hole formed in the insulating layer is installed up to the fixation part.

In the drive element according to this aspect, since the wiring part does not include a piezoelectric layer, unnecessary stress and vibration are less likely to occur at the installation position of the wiring part. Accordingly, damage to and characteristic deterioration of the drive element due to unnecessary stress and vibration during voltage application can be suppressed.

The effects and the significance of the present invention will be further clarified by the description of the embodiments below. However, the embodiments below are merely examples for implementing the present invention. The present invention is not limited to the description of the embodiments below in any way.

### BRIEF DESCRIPTION OF THE DRAWINGS

FIG. 1 is a plan view schematically showing a configuration of a drive element according to Embodiment 1;

FIG. 2A and FIG. 2B are a plan view and a cross-sectional view schematically showing a procedure for forming the drive element according to Embodiment 1, respectively;

FIG. 2C and FIG. 2D are a plan view and a cross-sectional view schematically showing the procedure for forming the drive element according to Embodiment 1, respectively;

FIG. 3A and FIG. 3B are a plan view and a cross-sectional view schematically showing the procedure for forming the drive element according to Embodiment 1, respectively;

FIG. 3C and FIG. 3D are a plan view and a cross-sectional view schematically showing the procedure for forming the drive element according to Embodiment 1, respectively;

FIG. 4A and FIG. 4B are a plan view and a cross-sectional view schematically showing the procedure for forming the drive element according to Embodiment 1, respectively;

FIG. 4C and FIG. 4D are a plan view and a cross-sectional view schematically showing the procedure for forming the drive element according to Embodiment 1, respectively;

FIG. 5A and FIG. 5B are a plan view and a cross-sectional view schematically showing the procedure for forming the drive element according to Embodiment 1, respectively;

FIG. 5C and FIG. 5D are a plan view and a cross-sectional view schematically showing the procedure for forming the drive element according to Embodiment 1, respectively;

FIG. 6A and FIG. 6B are a plan view and a cross-sectional view schematically showing the procedure for forming the drive element according to Embodiment 1, respectively;

FIG. 6C and FIG. 6D are a plan view and a cross-sectional view schematically showing the procedure for forming the drive element according to Embodiment 1, respectively;

FIG. 7A is a plan view schematically showing the procedure for forming the drive element according to Embodiment 1;

FIG. 7B to FIG. 7D are each a cross-sectional view schematically showing the procedure for forming the drive element according to Embodiment 1;

FIG. 8 is a see-through view schematically showing configurations of fixation layers installed on the lower surface side of fixation parts and a rib installed on the lower surface side of a movable part according to Embodiment 1;

FIG. 9A and FIG. 9B are each a cross-sectional view schematically showing configurations of a lower electrode, a piezoelectric layer, and an upper electrode according to a modification of Embodiment 1;

FIG. 10 is a plan view schematically showing a configuration of a drive element according to Embodiment 2;

FIG. 11A and FIG. 11B are a plan view and a cross-sectional view schematically showing the configuration of the drive element according to Embodiment 2, respectively;

FIG. 12A and FIG. 12B are a plan view and a cross-sectional view schematically showing a configuration of a drive element according to a modification of Embodiment 2, respectively;

FIG. 12C and FIG. 12D are a plan view and a cross-sectional view schematically showing the configuration of the drive element according to the modification of Embodiment 2, respectively;

FIG. 13 is a plan view schematically showing a configuration of a drive element according to Embodiment 3;

FIG. 14 is a plan view showing in detail a configuration on the X-axis negative side of the drive element according to Embodiment 3;

FIG. 15 is a plan view showing in detail a configuration on the X-axis negative side of a drive element according to Modification 1 of Embodiment 3;

FIG. 16 is a plan view showing in detail a configuration on the X-axis negative side of a drive element according to Modification 2 of Embodiment 3; and

FIG. 17 is a plan view schematically showing a configuration of a drive element according to another modification.

It should be noted that the drawings are solely for description and do not limit the scope of the present invention by any degree.

### DETAILED DESCRIPTION

Hereinafter, embodiments of the present invention will be described with reference to the drawings. For convenience, in each drawing, X, Y, and Z axes that are orthogonal to each other are additionally shown. The Z-axis positive direction is the vertical upward direction.

### Embodiment 1

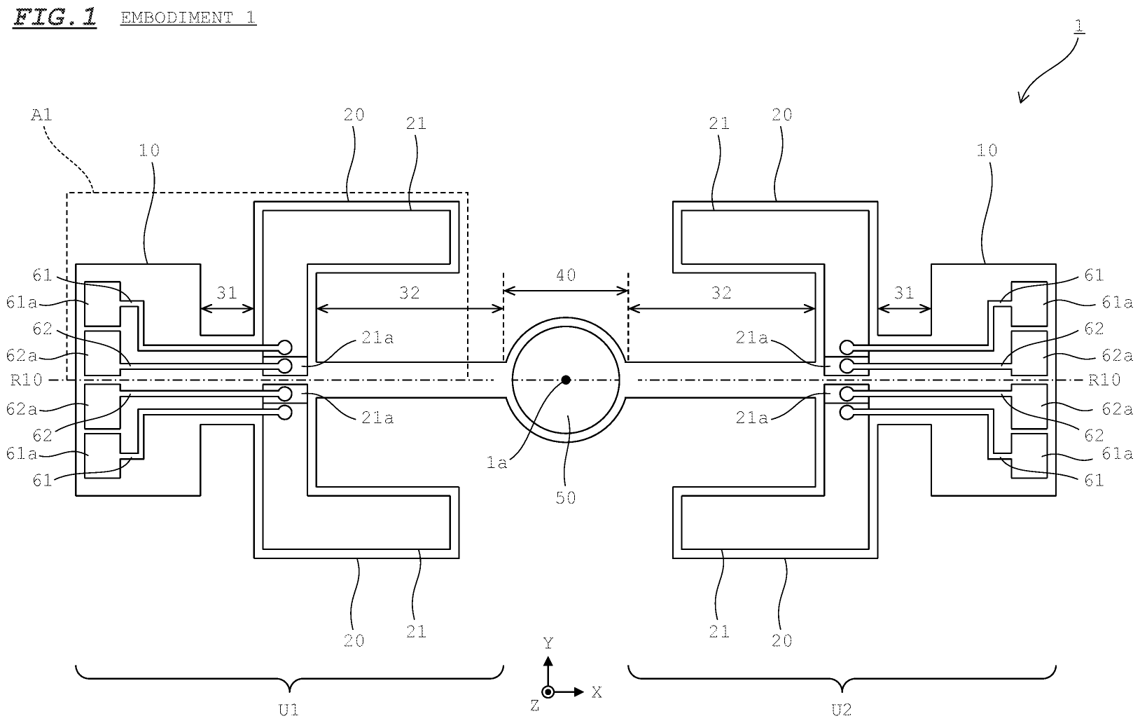

FIG. 1 is a plan view schematically showing a configuration of a drive element 1.

The drive element 1 includes a pair of fixation parts 10, four vibration parts 20, four drive parts 21, a pair of connection parts 31, a pair of connection parts 32, a movable part 40, a mirror 50, four wiring parts 61, and four wiring parts 62.

The drive element 1 is configured to be symmetrical in the X-axis direction and the Y-axis direction about a center 1a. The movable part 40 is provided at the center of the drive element 1, and rotates about a rotation axis R10 which passes through the center 1a and extends in the X-axis direction.

Drive units U1 and U2 are placed on the X-axis negative side and the X-axis positive side of the movable part 40, respectively. The drive unit U1 includes a fixation part 10, two vibration parts 20, two drive parts 21, connection parts 31 and 32, two wiring parts 61, and two wiring parts 62. The drive unit U2 has the same configuration as the drive unit U1.

The pair of fixation parts 10 are aligned in the direction of the rotation axis R10. When the drive element 1 is installed, the surface on the Z-axis negative side of each fixation part 10 is installed on an installation surface. The fixation parts 10 rotatably support the movable part 40.

Each vibration part 20 has an L-shape in a plan view. The two vibration parts 20 and the connection part 31 located on the X-axis positive side or the X-axis negative side of the center 1a have a tuning fork shape in a plan view. Each vibration part 20 is connected to the fixation part 10 via the connection part 31, and is connected to the movable part 40 via the connection part 32. The connection parts 31 and 32 extend along the rotation axis R10.

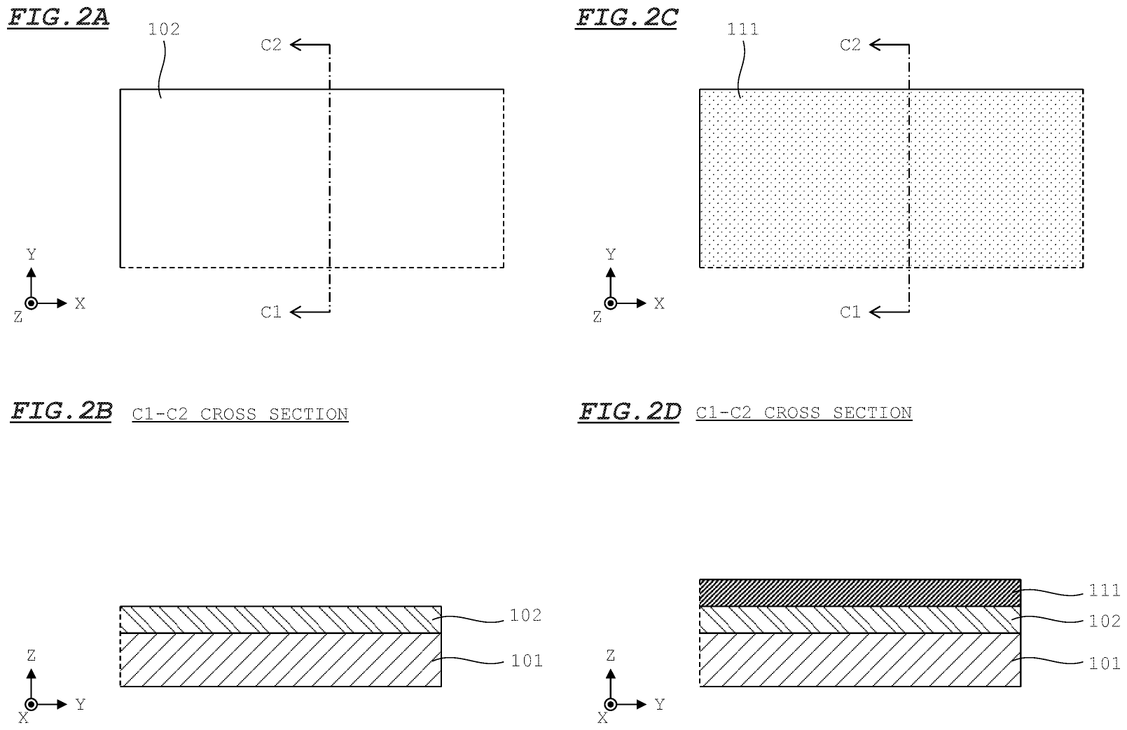

As described later with reference to FIG. 2A to FIG. 8, the vibration parts 20 and the connection parts 31 and 32 are composed of a base layer 101 and an insulating layer 102, the fixation part 10 is composed of the base layer 101, the insulating layer 102, and a fixation layer 11 which is installed on the lower surface of the base layer 101, and the movable part 40 is composed of the base layer 101, the insulating layer 102, and a rib 41 which is installed on the lower surface of the base layer 101.

An insulating layer (not shown) made of SiO₂ or the like may be formed between the base layer 101 and the fixation layer 11, and an insulating layer (not shown) may be formed between the base layer 101 and the rib 41 as well.

The mirror 50 is placed on the surface on the Z-axis positive side of the movable part 40. The movable part 40 and the mirror 50 have a circular shape centered on the center 1a in a plan view.

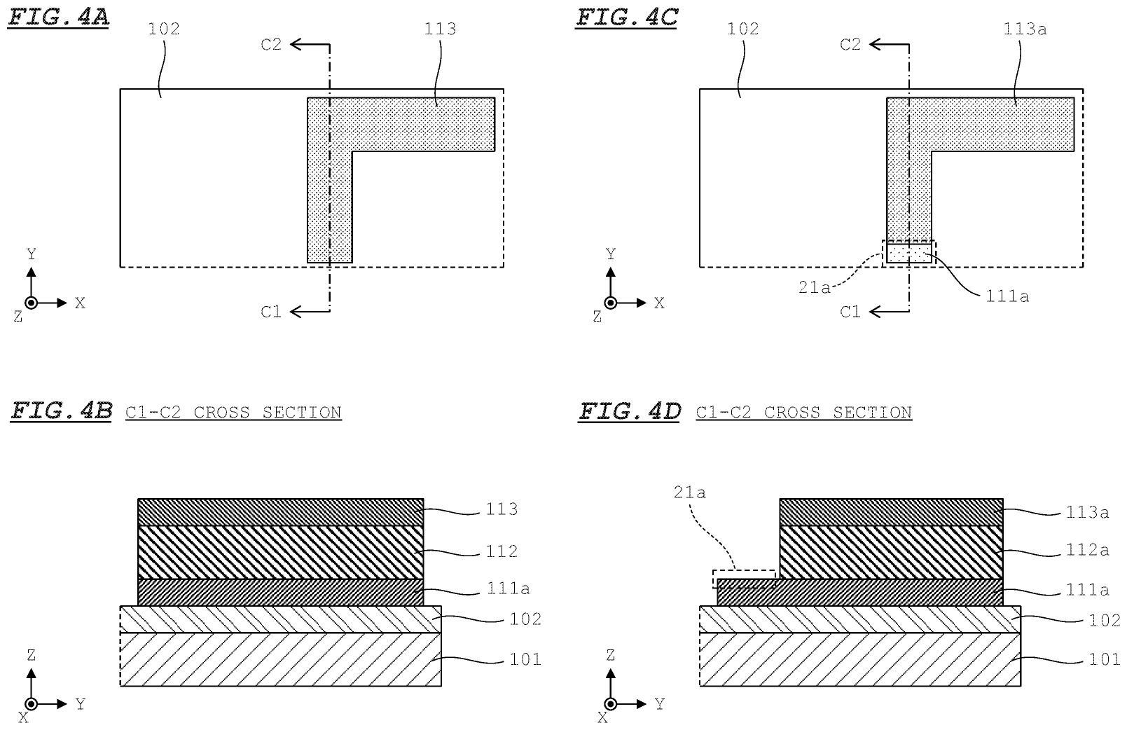

The drive part 21 which rotates the movable part 40 is placed on the upper surface side of each vibration part 20. The drive part 21 is a so-called piezoelectric transducer. A piezoelectric transducer is sometimes called piezoelectric actuator. As described later with reference to FIGS. 4A to 4D, the drive part 21 includes a lower electrode 111a, a piezoelectric layer 112a, an upper electrode 113a, and an insulating layer 121 which covers these layers. When a drive signal (voltage) is applied to the drive part 21, the vibration part 20 on which the drive part 21 is placed is driven.

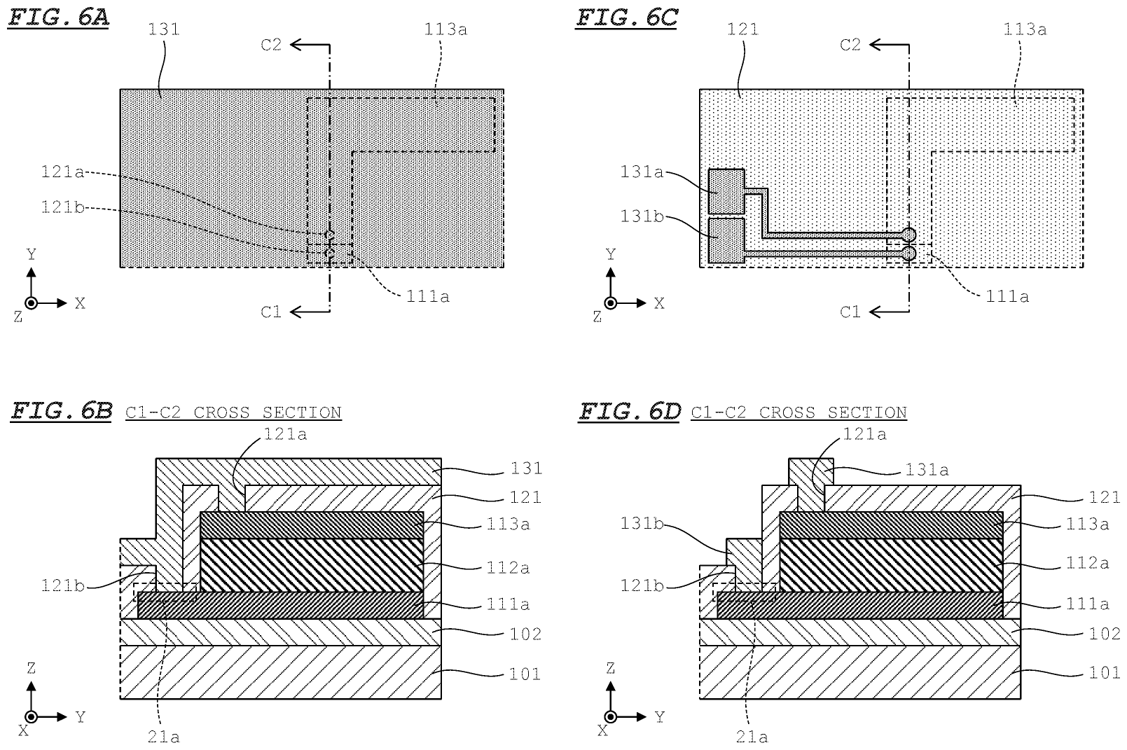

Each wiring part 61 is installed from the upper electrode 113a of the drive part 21 to the fixation part 10. An electrode 61a having a predetermined size is formed at an end portion of the wiring part 61 on the fixation part 10. Each wiring part 62 is installed from an exposed portion 21a of the lower electrode 111a of the drive part 21 to the fixation part 10. An electrode 62a having a predetermined size is formed at an end portion of the wiring part 62 on the fixation part 10. As described later with reference to FIGS. 6A to 6D, the wiring parts 61 and 62 are composed of single conductive layers 131a and 131b, respectively.

A cable (external wire) connected to an external power supply or the like is connected to each of the upper surfaces of the electrodes 61a and 62a by wire bonding. Alternatively, a BGA substrate or a substrate with through-wiring, which is connected to an external power supply or the like, may be connected to each of the upper surfaces of the electrodes 61a and 62a by metal bonding. When a drive signal (voltage) is applied to the drive part 21 via the cable or the substrate from the external power supply or the like, the piezoelectric layer 112a of the drive part 21 is deformed by an inverse piezoelectric effect, and the vibration part 20 vibrates so as to bend.

When the drive element 1 is driven, drive signals having opposite phases are applied to the drive parts 21 on two vibration parts 20, which are adjacent to each other in the Y-axis direction, such that these two vibration parts 20 vibrate in opposite directions in the Z-axis direction. In addition, drive signals having the same phase are applied to the drive parts 21 on two vibration parts 20, which face each other in the X-axis direction, such that these two vibration parts 20 vibrate in the same direction in the Z-axis direction. Accordingly, the movable part 40 and the mirror 50 rotate about the rotation axis R10, so that the direction of light incident on the mirror 50 is changed in accordance with the rotation angle of the mirror 50.

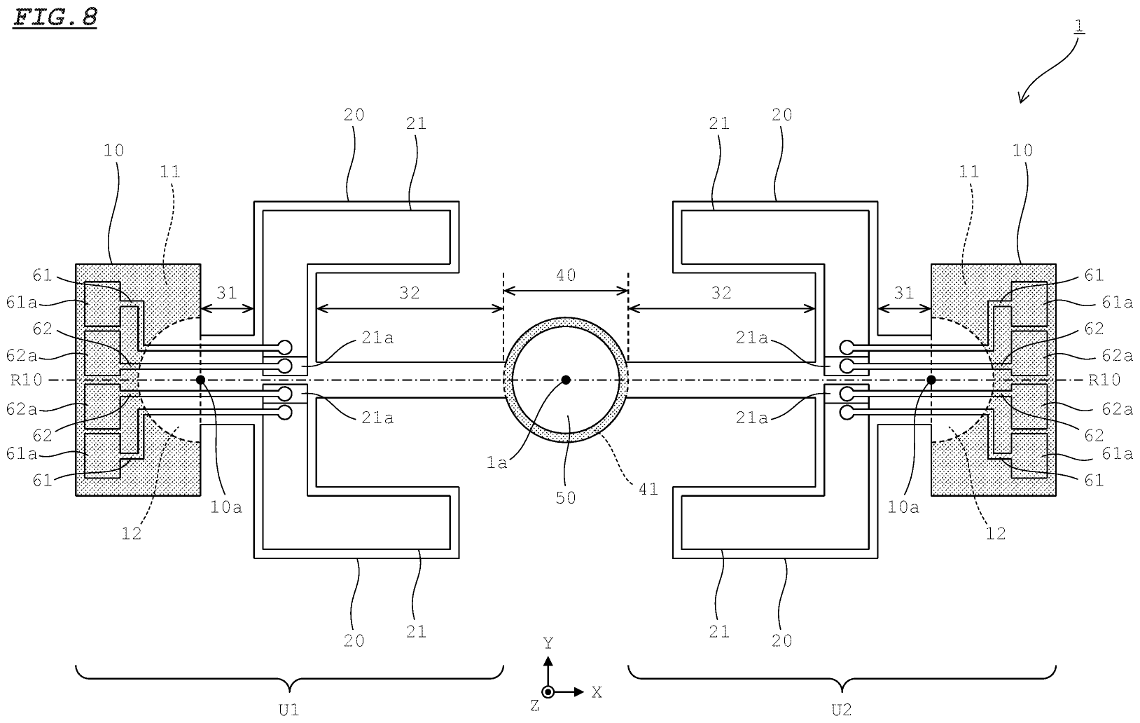

Next, a procedure for forming the drive element 1 will be described with reference to plan views and cross-sectional views in FIG. 2A to FIG. 7D and a see-through view in FIG. 8.

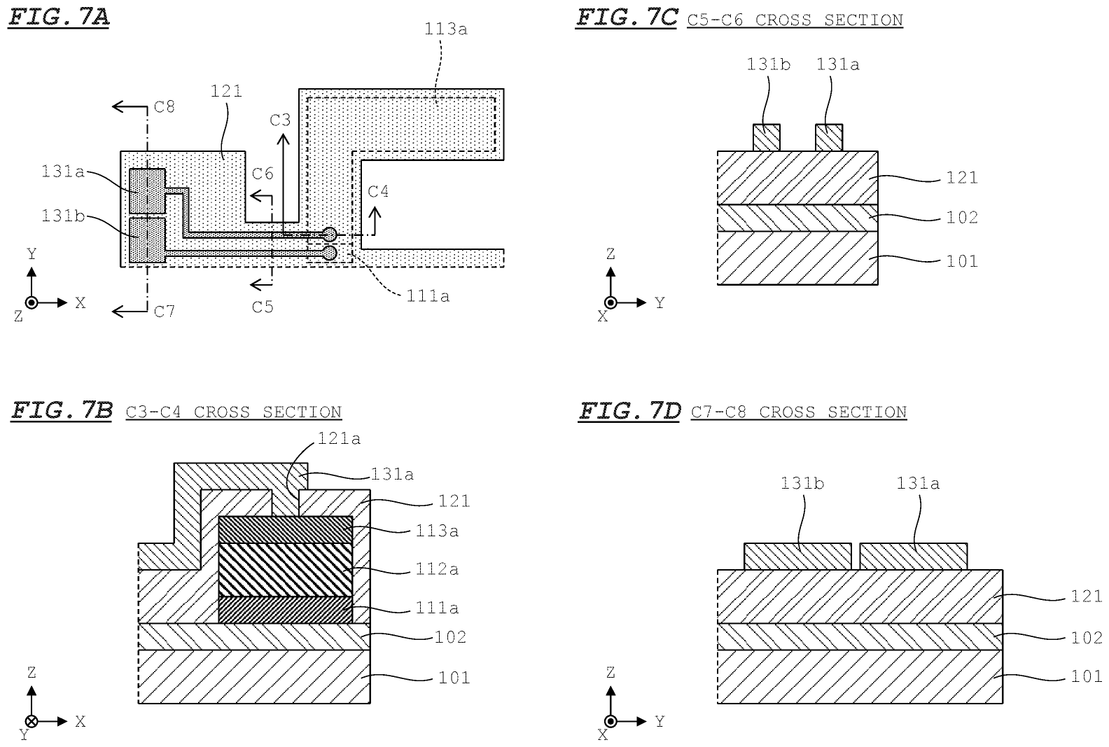

In FIG. 2A to FIG. 7D, for convenience, only a configuration of a region A1 (see FIG. 1) located on the X-axis negative side and the Y-axis positive side of the center 1a is shown. The cross-sectional views in FIGS. 2B, 2D, 3B, 3D, 4B, 4D, 5B, 5D, 6B, and 6D are views of C1-C2 cross-sections in the plan views in FIGS. 2A, 2C, 3A, 3C, 4A, 4C, 5A, 5C, 6A, and 6C as viewed in the X-axis negative direction, respectively. The cross-sectional views in FIGS. 7B, 7C, and 7D are a view of a C3-C4 cross-section in the plan view in FIG. 7A as viewed in the Y-axis positive direction, a view of a C5-C6 cross-section in the plan view in FIG. 7A as viewed in the X-axis negative direction, and a view of a C7-C8 cross-section in the plan view in FIG. 7A as viewed in the X-axis negative direction. FIG. 8 is a see-through view showing the positions of the fixation layers 11 and the rib 41.

As shown in FIGS. 2A and 2B, a substrate composed of the base layer 101 and the insulating layer 102 formed on the upper surface of the base layer 101 is prepared. The base layer 101 is made of, for example, silicon (Si), and the insulating layer 102 is composed of, for example, a thermal oxide film (SiO₂).

Subsequently, as shown in FIGS. 2C and 2D, a lower electrode 111 is formed on the upper surface of the insulating layer 102 in FIGS. 2A and 2B by sputtering. The lower electrode 111 is made of, for example, platinum (Pt).

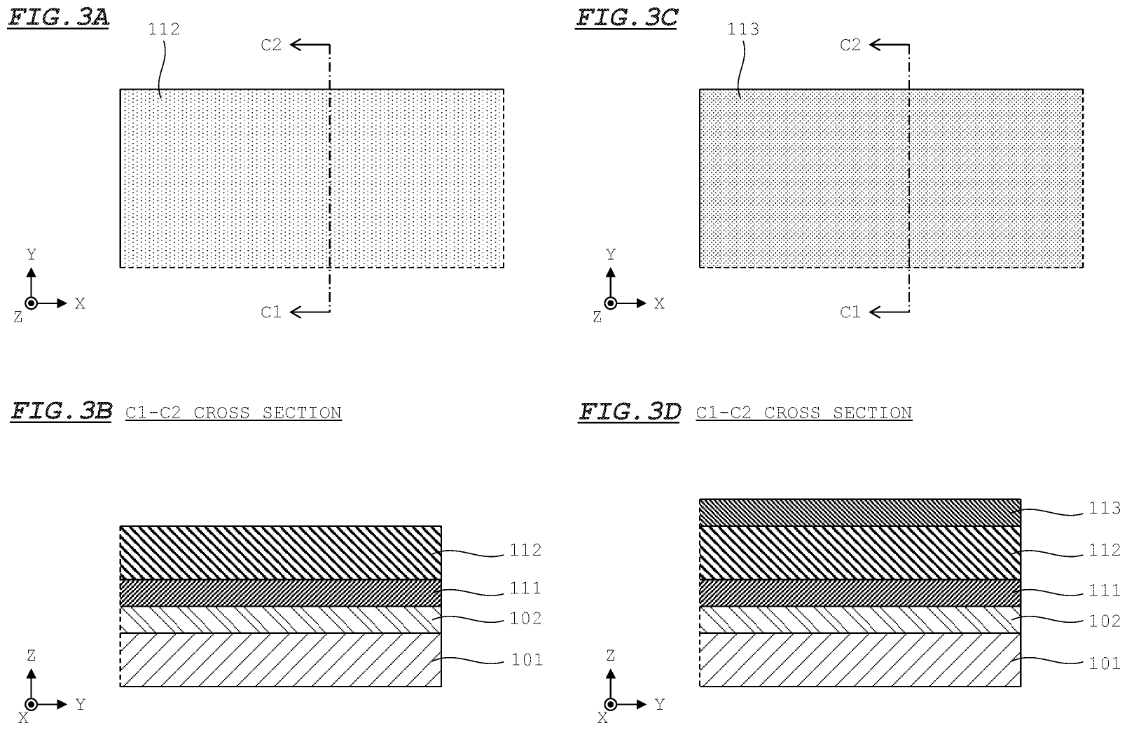

Subsequently, as shown in FIGS. 3A and 3B, a piezoelectric layer 112 is formed on the upper surface of the lower electrode 111 in FIGS. 2C and 2D by sputtering. The piezoelectric layer 112 is made of, for example, PZT (lead zirconate titanate: Pb(Zr, Ti)O₃).

Subsequently, as shown in FIGS. 3C and 3D, an upper electrode 113 is formed on the upper surface of the piezoelectric layer 112 in FIGS. 3A and 3B by sputtering. The upper electrode 113 is made of, for example, gold (Au).

Subsequently, as shown in FIGS. 4A and 4B, the lower electrode 111, the piezoelectric layer 112, and the upper electrode 113 in FIGS. 3C and 3D are removed by etching such that the lower electrode 111, the piezoelectric layer 112, and the upper electrode 113 remain in a region corresponding to the drive part 21 in FIG. 1. Accordingly, the lower electrode 111a of the drive part 21 is formed.

Subsequently, as shown in FIGS. 4C and 4D, the piezoelectric layer 112 and the upper electrode 113 in FIGS. 4A and 4B are removed by etching such that the piezoelectric layer 112 and the upper electrode 113 are removed from a region corresponding to the exposed portion 21a in FIG. 1. Accordingly, the lower electrode 111 is opened upward at the exposed portion 21a, and the piezoelectric layer 112a and the upper electrode 113a of the drive part 21 are formed.

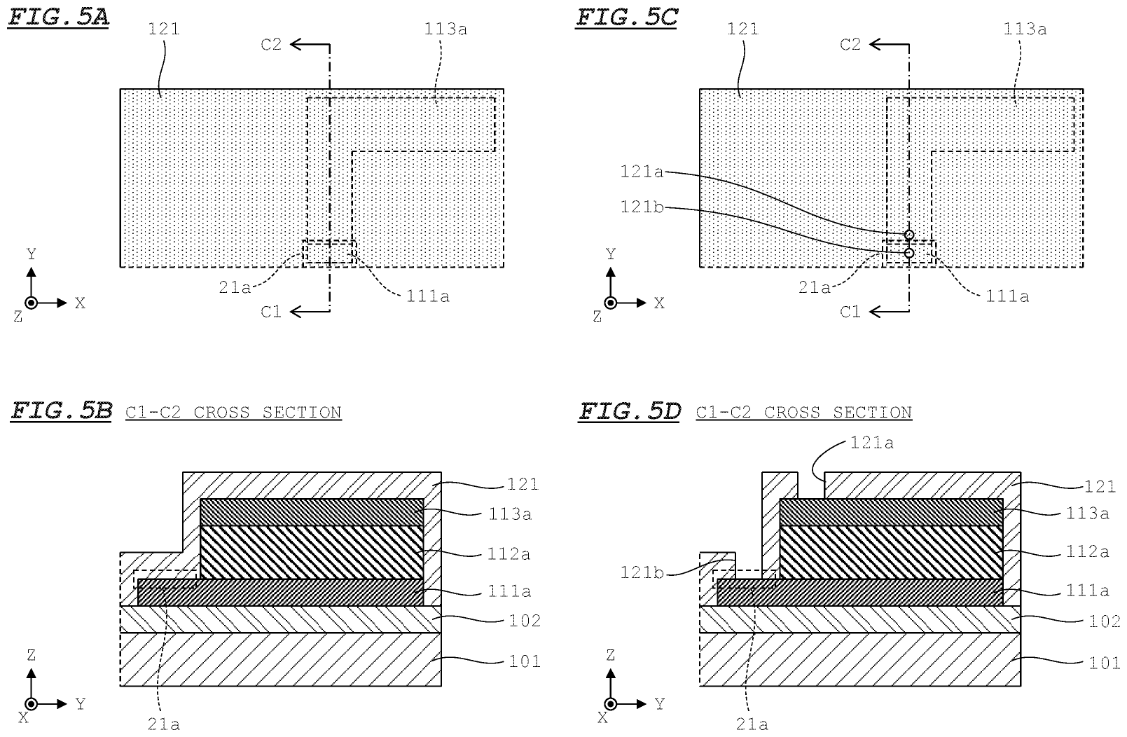

Subsequently, as shown in FIGS. 5A and 5B, the insulating layer 121 is formed on the entire upper surface in FIGS. 4C and 4D by sputtering, CVD, ALD, or the like. The insulating layer 121 is made of, for example, SiN or Al₂O₃. The insulating layer 121 may be made of a material having a low Young's modulus (a material having low mechanical rigidity), or may be made of, for example, a resin material such as photosensitive polyimide.

Subsequently, as shown in FIGS. 5C and 5D, contact holes 121a and 121b are respectively formed in the insulating layer 121 located near an end portion on the Y-axis negative side of the upper electrode 113a and in the insulating layer 121 located near the center of the exposed portion 21a in FIGS. 5A and 5B. As a result of the formation of the contact hole 121a, the upper electrode 113a located below the contact hole 121a is opened upward, and as a result of the formation of the contact hole 121b, the lower electrode 111a located below the contact hole 121b is opened upward.

Subsequently, as shown in FIGS. 6A and 6B, a conductive layer 131 is formed on the entire upper surface in FIGS. 5C and 5D by sputtering. The conductive layer 131 is made of, for example, gold (Au). At this time, the conductive layer 131 is connected to the upper electrode 113a through the contact hole 121a, and is connected to the lower electrode 111a through the contact hole 121b.

Subsequently, as shown in FIGS. 6C and 6D, the conductive layer 131 in FIGS. 6A and 6B is removed by etching such that the conductive layer 131 remains in regions corresponding to the wiring parts 61 and 62 in FIG. 1. Accordingly, the conductive layer 131a corresponding to the wiring part 61 is formed, and the conductive layer 131b corresponding to the wiring part 62 is formed. That is, as shown in FIG. 1, the wiring part 61 composed of the conductive layer 131a and the wiring part 62 composed of the conductive layer 131b are formed in a region from the drive part 21 to the fixation part 10, and the electrodes 61a and 62a are formed in a region corresponding to the fixation part 10.

Subsequently, as shown in FIGS. 7A to 7D, the base layer 101, the insulating layer 102, and the insulating layer 121 in FIGS. 6C and 6D are removed such that the base layer 101, the insulating layer 102, and the insulating layer 121 remain in regions corresponding to the fixation part 10 and the vibration part 20 in FIG. 1. As shown in FIGS. 7B to 7D, the conductive layer 131a extends from the upper electrode 113 through the contact hole 121a and passes over the upper surface of the insulating layer 121 to the fixation part 10. Similarly, the conductive layer 131b extends from the lower electrode 111 through the contact hole 121b (see FIG. 6D) and passes over the upper surface of the insulating layer 121 to the fixation part 10.

For convenience, FIG. 2A to FIG. 7D illustrate only the procedure for forming the region A1 in FIG. 1, but in actuality, the entire drive element 1 in FIG. 1 is formed at the same time.

Then, as shown in FIG. 8, the fixation layer 11 having a predetermined thickness and made of silicon (Si) is installed on the lower surface of the base layer 101 corresponding to each fixation part 10. Each fixation layer 11 is provided outside a position spreading in a fan shape from a center 10a of the connection position between the connection part 31 and the fixation part 10 as shown by hatching. Accordingly, a face spring part 12 having the same thickness as the connection part 31 is formed in a predetermined range on the fixation part 10 side from the connection position between the fixation part 10 and the connection part 31. The face spring part 12 of Embodiment 1 spreads in a fan shape from the center 10a of the connection position and is formed in a range on the center 10a side with respect to the electrodes 61a and 62a. The shape of the face spring part 12 is not limited to a fan shape, and may be a trapezoidal or polygonal shape.

If each face spring part 12 is located near the connection position between the connection part 31 and the fixation part 10 as described above, when each vibration part 20 vibrates, concentration of high stress on the connection position between the connection part 31 and the fixation part 10 can be suppressed by the cushioning action of the face spring part 12. Accordingly, damage at the interface between the fixation part 10 and the connection part 31 due to drive vibration of the vibration part 20 can be suppressed.

Subsequently, as shown in FIG. 8, the rib 41 having a predetermined thickness and made of silicon (Si) is installed on the lower surface of the base layer 101 corresponding to the movable part 40. The rib 41 is provided at the outer periphery of the lower surface of the base layer 101 corresponding to the movable part 40 as shown by hatching. The rib 41 increases the strength of the movable part 40. Then, the mirror 50 is placed on the upper surface of the movable part 40. Thus, the drive element 1 is completed.

The fixation layers 11 and the rib 41 may be formed by placing an SOI substrate or the like, in which a silicon layer is formed, on the entire lower surface of the base layer 101 in FIGS. 2A and 2B, and removing the SOI substrate or the like such that the regions of the fixation layers 11 and the rib 41 remain as shown in FIG. 8. The fixation layers 11 and the rib 41 do not necessarily need to be placed and may be omitted.

### Effects of Embodiment 1

According to Embodiment 1, the following effects are achieved.

The upper electrode 113a and the lower electrode 111a are placed with the piezoelectric layer 112a interposed therebetween, the insulating layer 121 covers the piezoelectric layer 112a, the upper electrode 113a, and the lower electrode 111a, and each wiring part 61 composed of the single conductive layer 131a which is connected to the upper electrode 113a via the contact hole 121a formed in the insulating layer 121 is installed up to the fixation part 10. With this configuration, since the wiring part 61 does not include a piezoelectric layer, unnecessary stress and vibration due to an inverse piezoelectric effect are less likely to occur at the installation position of the wiring part 61. Accordingly, damage to and characteristic deterioration of the drive element 1 due to unnecessary stress and vibration during voltage application can be suppressed.

Specifically, since there is no piezoelectric layer in each connection part 31 which connects the vibration parts 20 to the fixation part 10, high stress due to a piezoelectric effect is less likely to be generated in the connection part 31 when a voltage is applied via the conductive layer 131a. Therefore, damage to the connection part 31 due to stress during voltage application can be suppressed. In addition, since there is no piezoelectric layer in the fixation part 10 near the connection part 31, high stress due to a piezoelectric effect is less likely to be concentrated on the face spring part 12 when a voltage is applied via the conductive layer 131a. Therefore, concentration of high stress, due to a piezoelectric effect, on the connection position between the connection part 31 and the fixation part 10 and the face spring part 12 of the fixation part 10 can be avoided. As a result, damage due to unnecessary stress during voltage application can be suppressed in the drive element 1 as a whole.

Since there is no piezoelectric layer at the installation position of the wiring part 61, unnecessary vibration does not occur at the connection part 31 and the fixation part 10 during voltage application. Therefore, deterioration of the drive characteristics of the movable part 40 due to unnecessary vibration can be suppressed.

Since there is no piezoelectric layer at the installation position of the wiring part 61, the capacitance at this installation position can be reduced. Accordingly, it is possible to reduce power consumption.

Since there is no piezoelectric layer at the installation position of the wiring part 61, the adverse effects (warpage and stress concentration) due to the internal stress (film stress) of a piezoelectric layer can be suppressed.

The lower electrode 111a includes the exposed portion 21a on which the piezoelectric layer 112a and the upper electrode 113a are not overlaid, and each wiring part 62 (other wiring part) composed of the single conductive layer 131b which is connected to the exposed portion 21a via the contact hole 121b (other contact hole) formed in the insulating layer 121 is installed up to the fixation part 10. Accordingly, by adjusting the voltage of the lower electrode 111a as appropriate, each drive part 21 can be accurately controlled to be in a desired drive state. In addition, since there is no piezoelectric layer at the installation position of the wiring part 62, the same effects as the above-described effects due to the fact that there is no piezoelectric layer at the installation position of the wiring part 61 are achieved.

Since there is no piezoelectric layer in any of the two wiring parts 61 and the two wiring parts 62 on the X-axis positive side or the X-axis negative side of the center 1a, the parasitic capacitance between these four wiring parts can be significantly reduced. Therefore, noise propagation between these four wiring parts can be suppressed, so that deterioration of the drive characteristics of the movable part 40 can be suppressed.

Each connection part 31 connects the vibration parts 20, on which the drive parts 21 are placed, and the fixation part 10, and each face spring part 12 having the same thickness as the connection part 31 is formed in the predetermined range on the fixation part 10 side from the connection position between the fixation part 10 and the connection part 31 as shown in FIG. 8. With this configuration, when each vibration part 20 vibrates, concentration of high stress on the connection position between the connection part 31 and the fixation part 10 can be suppressed by the cushioning action of the face spring part 12. Accordingly, damage at the interface between the fixation part 10 and the connection part 31 due to drive vibration of the vibration part 20 can be suppressed. In addition, since there is no piezoelectric layer in the face spring part 12, high stress due to a piezoelectric effect is less likely to be concentrated on the face spring part 12 when a voltage is applied via the conductive layer 131a. Accordingly, concentration of high stress, due to a piezoelectric effect, on the face spring part 12 can be avoided, so that damage to the face spring part 12 can be suppressed.

An end portion on the fixation part 10 side of the conductive layer 131a is widened to form the electrode 61a, and an end portion on the fixation part 10 side of the conductive layer 131b is widened to form the electrode 62a. If there is a piezoelectric layer at the positions of the electrodes 61a and 62a, the piezoelectric layer is damaged by ultrasonic loading or thermal stress during wire bonding of an external wire or metal bonding of a BGA substrate or a substrate with through-wiring with respect to the electrodes 61a and 62a. Therefore, when a high voltage is applied to the electrodes 61a and 62a, a short circuit may occur at the electrodes 61a and 62a, resulting in damage to the drive element 1. In the present embodiment, since there is no piezoelectric layer at the positions of the electrodes 61a and 62a, such a problem can be avoided.

The insulating layer 121 is placed from each drive part 21 to each fixation part 10. In the case where the insulating layer 121 is made of a material having a low Young's modulus (e.g., a resin material such as photosensitive polyimide, or the like), damage (stress migration, etc.) to the conductive layers 131a and 131b due to vibration can be mitigated at each connection part 31 and each vibration part 20, and concentration of stress on each face spring part 12 can be suppressed. Therefore, the durability of the drive element 1 can be improved.

As shown in FIG. 1, the two drive units U1 and U2 are placed with the movable part 40 interposed therebetween. Accordingly, the rotation angle of the movable part 40 can be larger than that in the case where a drive unit is placed only on one side in the X-axis direction with respect to the movable part 40. In addition, the movable part 40 can be held stably and can have high resistance to external impact.

### Modification of Embodiment 1

In Embodiment 1, as shown in FIGS. 4B and 4D, the lower electrode 111a, the piezoelectric layer 112a, and the upper electrode 113a are removed by etching such that the widths in the plane direction thereof are equal to each other. In this case, the side surfaces of the lower electrode 111a, the piezoelectric layer 112a, and the upper electrode 113a are perpendicular to a horizontal plane (X-Y plane). In contrast, in this modification, etching is performed such that the widths in the plane direction of the stacked lower electrode 111a, piezoelectric layer 112a, and upper electrode 113a are smaller in this order.

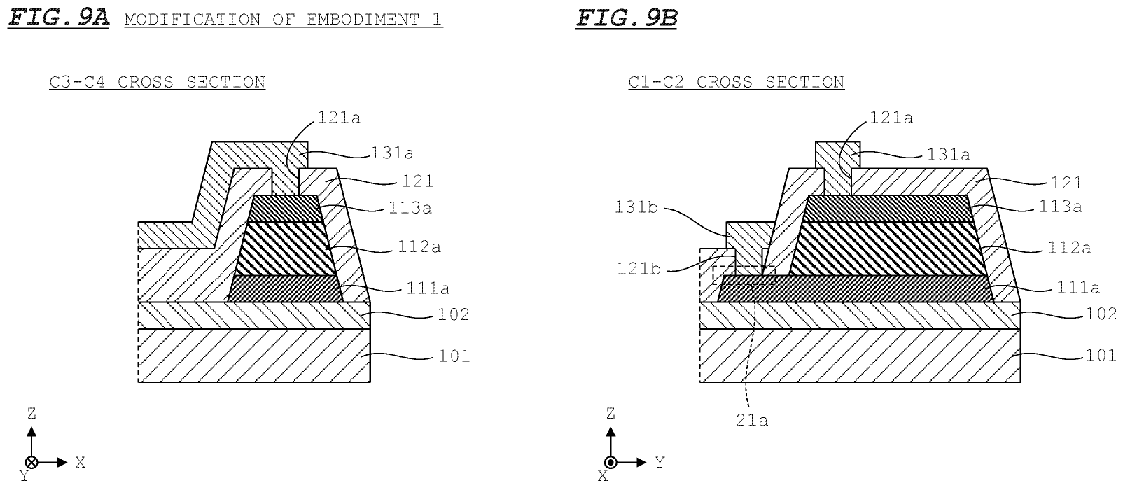

FIGS. 9A and 9B are each a cross-sectional view schematically showing the configuration of the lower electrode 111a, the piezoelectric layer 112a, and the upper electrode 113a formed by etching according to this modification. FIG. 9A is a view of a C3-C4 cross-section of FIG. 7A as viewed in the Y-axis positive direction, and FIG. 9B is a view of a C1-C2 cross-section of FIG. 6C as viewed in the X-axis negative direction.

As shown in FIGS. 9A and 9B, the lower electrode 111a, the piezoelectric layer 112a, and the upper electrode 113a are etched such that the widths in the plane direction thereof become narrower in the upward direction (Z-axis positive direction). Accordingly, it is easier to form the insulating layer 121 on the side portions of the lower electrode 111a, the piezoelectric layer 112a, and the upper electrode 113a, so that the thickness of the insulating layer 121 at these side portions becomes larger. Therefore, as shown in FIGS. 9A and 9B, a short-circuit between: the upper electrode 113a; and the lower electrode 111a and the piezoelectric layer 112a due to the conductive layer 131a (wiring part 61 in FIG. 1) which is connected to the upper electrode 113a can be reliably prevented. In addition, as shown in FIG. 9B, a short-circuit between: the upper electrode 113a and the piezoelectric layer 112a; and the lower electrode 111a due to the conductive layer 131b (wiring part 62 in FIG. 1) which is connected to the lower electrode 111a can be reliably prevented.

### Embodiment 2

In Embodiment 1 above, on each vibration part 20, only the drive part 21 for driving the vibration part 20 is placed. However, in Embodiment 2, a monitoring part for monitoring the operation of the drive part 21 is further placed.

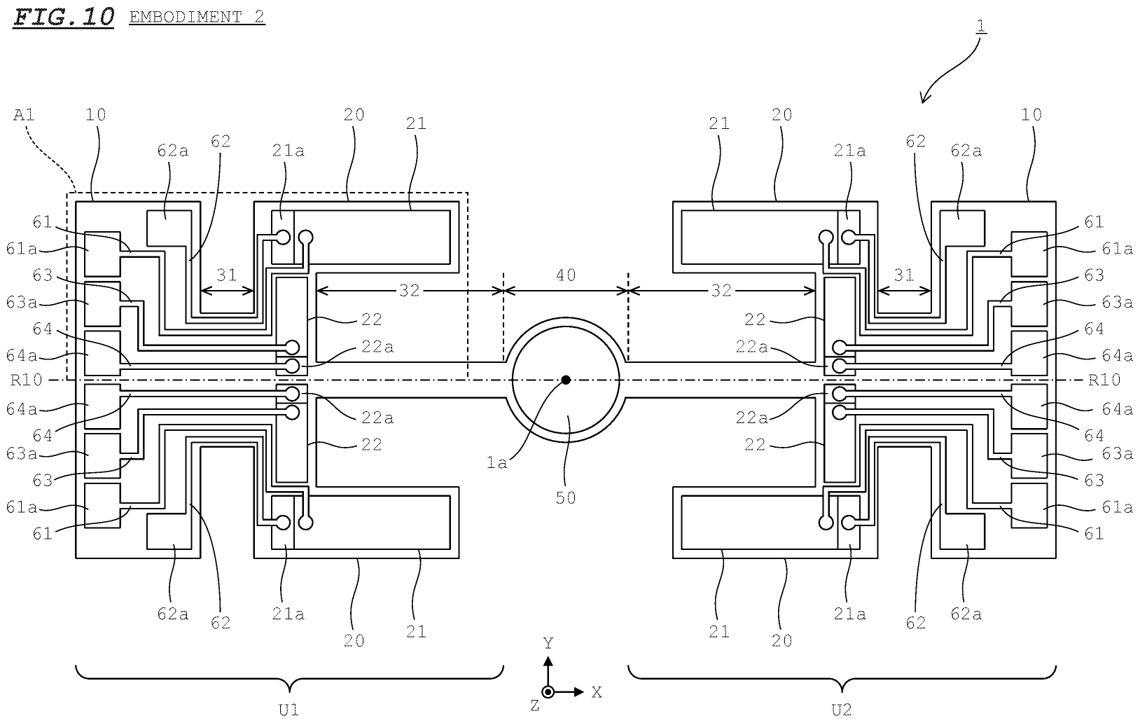

FIG. 10 is a plan view schematically showing a configuration of a drive element 1 according to Embodiment 2.

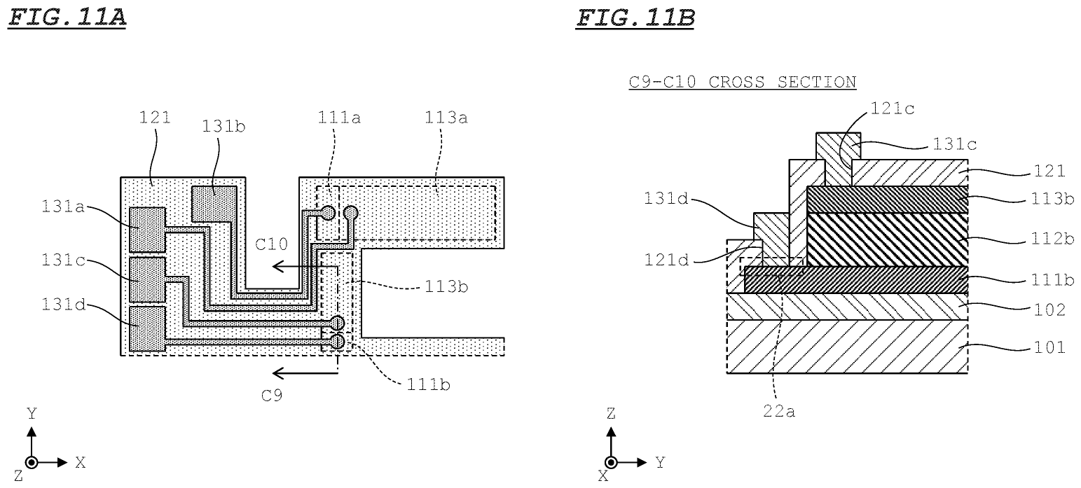

In addition to the configuration of Embodiment 1 in FIG. 1, the drive element 1 includes four monitoring parts 22, four wiring parts 63, and four wiring parts 64. As described later with reference to FIGS. 11A and 11B, the monitoring parts 22 and the wiring parts 63 and 64 have the same lamination structures as the drive parts 21 and the wiring parts 61 and 62, respectively.

In Embodiment 2 as well, two drive units U1 and U2 are placed with the movable part 40 interposed therebetween. Compared to the configuration of Embodiment 1 in FIG. 1, the drive unit U1 further includes two monitoring parts 22, two wiring parts 63, and two wiring parts 64. The drive unit U2 has the same configuration as the drive unit U1.

The four monitoring parts 22 are placed on the upper surface side of the four vibration parts 20, respectively, and on each vibration part 20, the monitoring part 22 is placed between the drive part 21 and the connection part 31. As described later with reference to FIGS. 11A and 11B, the monitoring part 22 includes a lower electrode 111b, a piezoelectric layer 112b, an upper electrode 113b, and an insulating layer 121 which covers these respective layers.

Each wiring part 63 is installed from the upper electrode 113b of the monitoring part 22 to the fixation part 10. An electrode 63a having a predetermined size is formed on an end portion of the wiring part 63 on the fixation part 10. Each wiring part 64 is installed from an exposed portion 22a of the lower electrode 111b of the monitoring part 22 to the fixation part 10. An electrode 64a having a predetermined size is formed on an end portion of the wiring part 64 on the fixation part 10. As described later with reference to FIGS. 11A and 11B, the wiring parts 63 and 64 are composed of single conductive layers 131c and 131d, respectively.

A cable (external wire) connected to an external circuit or the like is connected to each of the upper surfaces of the electrodes 63a and 64a by wire bonding. Alternatively, a BGA substrate or a substrate with through-wiring, which is connected to an external circuit or the like, may be connected to each of the upper surfaces of the electrodes 63a and 64a by metal bonding. When each vibration part 20 bends by driving each drive part 21, a detection signal (current or charge) generated in the monitoring part 22 due to a piezoelectric effect is outputted to the external circuit via the cable or the substrate. Accordingly, the operation of the drive part 21 can be monitored by the external circuit.

FIGS. 11A and 11B are a plan view and a cross-sectional view schematically showing a configuration of the drive element 1 in a region A1 in FIG. 10, respectively. The cross-sectional view in FIG. 11B is a view of a C9-C10 cross-section in a plan view in FIG. 11A as viewed in the X-axis negative direction.

Each monitoring part 22 is formed in parallel with the formation of each layer in Embodiment 1, in the same manner as each drive part 21. The lower electrode 111, the piezoelectric layer 112, and the upper electrode 113 in FIGS. 3C and 3D are removed by etching such that the lower electrode 111, the piezoelectric layer 112, and the upper electrode 113 remain in a region corresponding to each monitoring part 22 in FIG. 10. Accordingly, the lower electrode 111b, the piezoelectric layer 112b, and the upper electrode 113b which form the monitoring part 22 are formed, and the lower electrode 111b is opened upward at the exposed portion 22a.

As in FIGS. 9A and 9B, the monitoring part 22 may also be configured such that the widths in the plane direction of the stacked lower electrode 111b, piezoelectric layer 112b, and upper electrode 113b are smaller in this order. Accordingly, it is easier to form the insulating layer 121 on the side portions of the lower electrode 111b, the piezoelectric layer 112b, and the upper electrode 113b, so that unnecessary short circuits can be reliably prevented.

A contact hole 121c is formed in the insulating layer 121 above the upper electrode 113b, and a contact hole 121d is formed in the insulating layer 121 above the exposed portion 22a of the lower electrode 111b. After the conductive layer 131 in FIGS. 6A and 6B is formed in the entire drive element 1, the conductive layer 131 is removed by etching such that the conductive layer 131 remains in regions corresponding to the wiring parts 63 and 64 in FIG. 10. Accordingly, as shown in FIGS. 11A and 11B, the conductive layer 131c corresponding to the wiring part 63 and the conductive layer 131d corresponding to the wiring part 64 are formed. At this time, as shown in FIG. 11B, the conductive layer 131c is connected to the upper electrode 113b via the contact hole 121c, and the conductive layer 131d is connected to the exposed portion 22a of the lower electrode 111b via the contact hole 121d.

As described above, each monitoring part 22 can be formed by the same process flow as each drive part 21, and the manufacturing process can be simplified by forming each monitoring part 22 and each drive part 21 at the same timing.

### Effects of Embodiment 2

According to Embodiment 2, the following effects are achieved.

In each monitoring part 22 as well, as in each drive part 21, the upper electrode 113b and the lower electrode 111b are placed with the piezoelectric layer 112b interposed therebetween, the insulating layer 121 covers the piezoelectric layer 112b, the upper electrode 113b, and the lower electrode 111b, and each wiring part 63 composed of the single conductive layer 131c which is connected to the upper electrode 113b via the contact hole 121c formed in the insulating layer 121 is installed up to the fixation part 10. With this configuration, the vibration state of the drive part 21 can be grasped by detecting a detection signal (current or charge) from the monitoring part 22.

Since there is no piezoelectric layer at the installation position of the wiring part 63, generation of a signal in the wiring part 61 due to a piezoelectric effect is avoided. Therefore, the S/N ratio of a detection signal for monitoring the operation of the drive part 21 can be improved.

The lower electrode 111b includes the exposed portion 22a on which the piezoelectric layer 112b and the upper electrode 113b are not overlaid, and each wiring part 64 (other wiring part) composed of the single conductive layer 131d which is connected to the exposed portion 22a via the contact hole 121d (other contact hole) formed in the insulating layer 121 is installed up to the fixation part 10. When the lower electrode 111b of the monitoring part 22 is drawn separately from the lower electrode 111a of the drive part 21 as described above, a signal on the drive part 21 side can be inhibited from being superimposed as noise on the monitoring part 22 side, so that higher accuracy of a detection signal can be achieved.

Since there is no piezoelectric layer in any of the two wiring parts 61, the two wiring parts 62, the two wiring parts 63, and the two wiring parts 64 on the X-axis positive side or the X-axis negative side of the center 1a, the parasitic capacitance between these eight wiring parts can be significantly reduced. Accordingly, noise propagation between these eight wiring parts can be suppressed, so that deterioration of the drive characteristics of the movable part 40 can be suppressed, and the S/N ratio of a detection signal for monitoring the operation of each drive part 21 can also be improved.

### Modification of Embodiment 2

In Embodiment 2, as shown in FIG. 10, the wiring parts 61 and 62 drawn from each drive part 21 are installed up to the fixation part 10 so as to bypass the region of the monitoring part 22, but may be overlaid above the monitoring part 22.

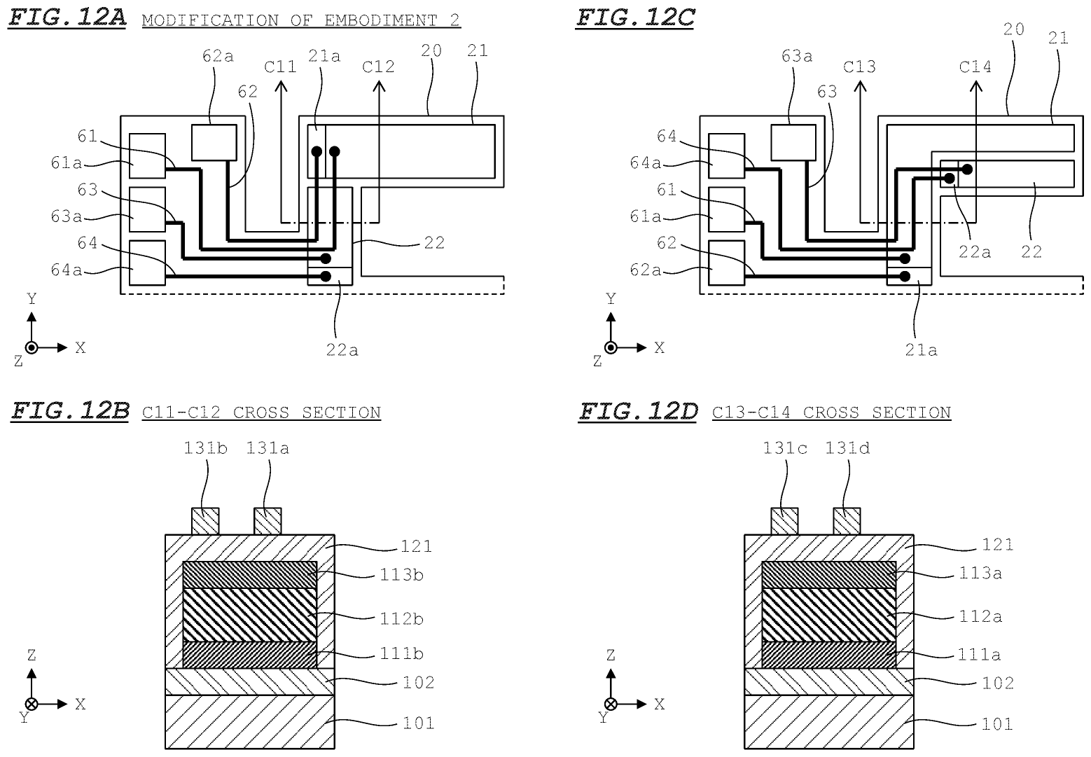

FIGS. 12A and 12B are a plan view and a cross-sectional view schematically showing a configuration of the drive element 1 in the region A1 in FIG. 10 according to this modification, respectively. The cross-sectional view in FIG. 12B is a view of a C11-C12 cross-section in the plan view in FIG. 12A as viewed in the Y-axis positive direction.

As shown in FIG. 12A, the wiring parts 61 and 62 drawn from the drive part 21 extend in the Y-axis negative direction, then bend in the X-axis negative direction, and extend to the fixation part 10. In this case, as shown in FIG. 12B, the conductive layers 131a and 131b corresponding to the wiring parts 61 and 62, respectively, are placed on the upper surface of the insulating layer 121 of the monitoring part 22.

When the wiring parts 61 and 62 (conductive layers 131a and 131b) connected to the drive part 21 are formed so as to traverse the upper surface of the insulating layer 121 of the monitoring part 22 as described above, the area of the monitoring part 22 can be increased, so that it is possible to increase the detection signal from the monitoring part 22, thereby making it possible to detect the vibration state of the drive part 21 with high accuracy.

As shown in FIGS. 12C and 12D, the wiring parts 63 and 64 (conductive layers 131c and 131d) connected to the monitoring part 22 may be formed so as to traverse the upper surface of the insulating layer 121 of the drive part 21. In this case, the area of the drive part 21 can be increased, thereby allowing the drive part 21 to vibrate greatly.

### Embodiment 3

In Embodiment 1, the vibration parts 20 are placed in a tuning fork shape, but in Embodiment 3, vibration parts are placed in a meander shape.

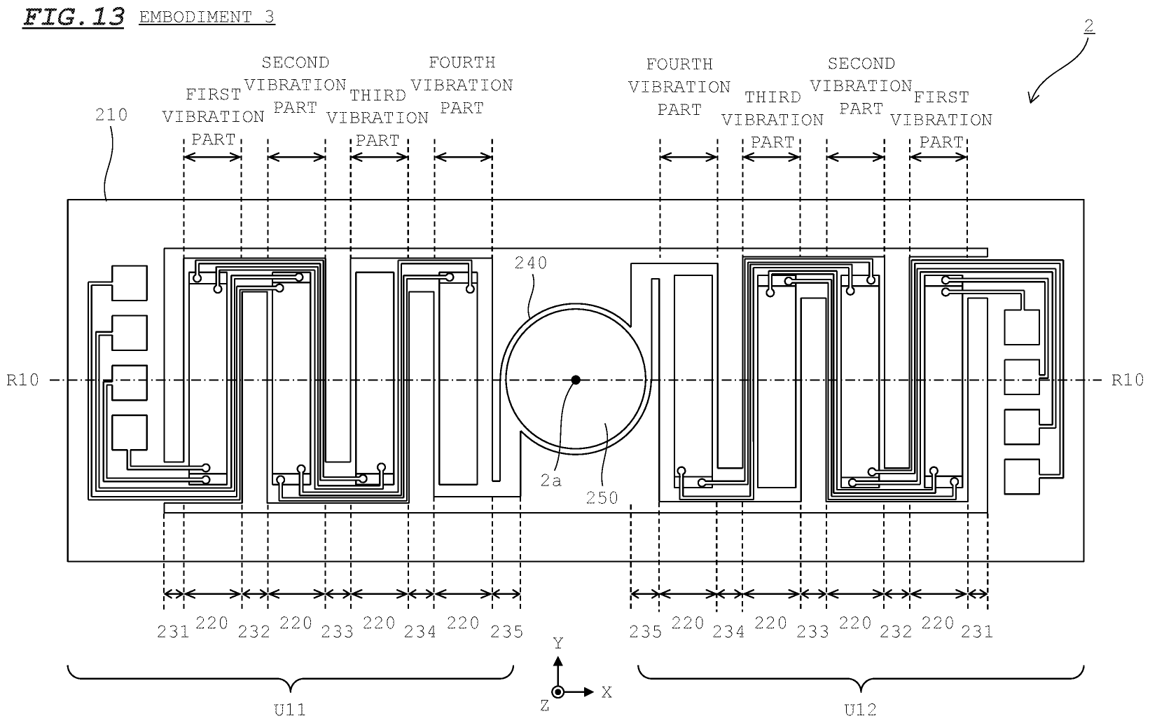

FIG. 13 is a plan view schematically showing a configuration of a drive element 2 according to Embodiment 3.

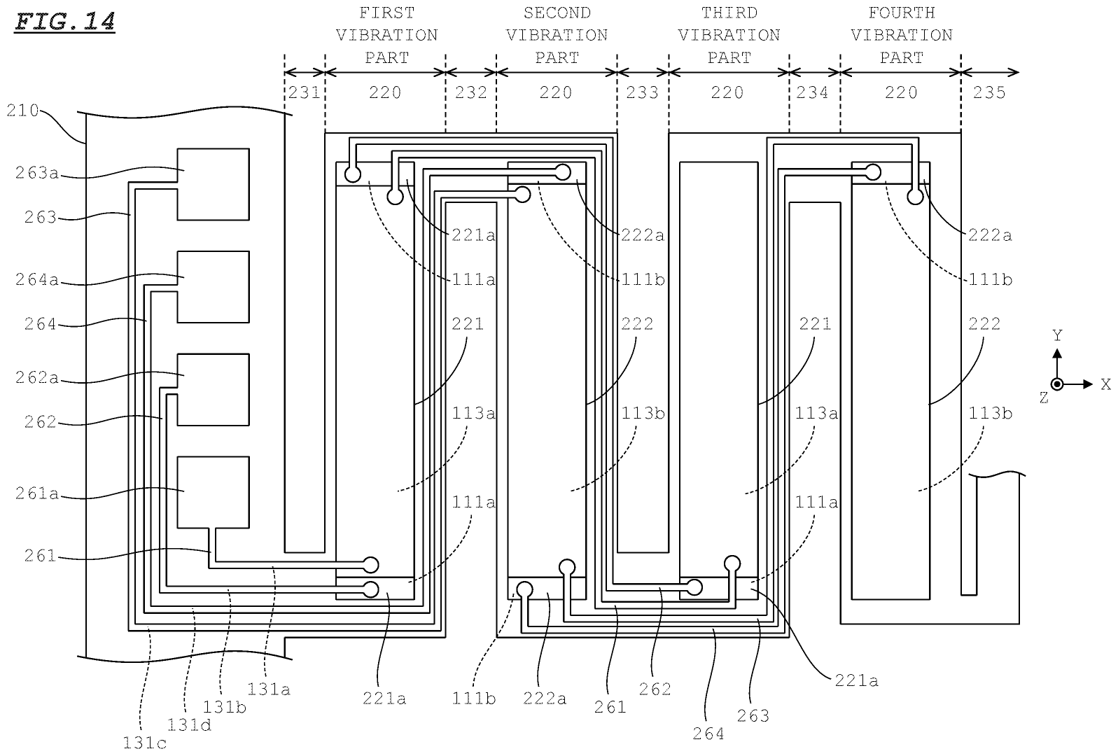

The drive element 2 includes a fixation part 210, eight vibration parts 220, four drive parts 221, four monitoring parts 222, a pair of connection parts 231, a pair of connection parts 232, a pair of connection parts 233, a pair of connection parts 234, a pair of connection parts 235, a movable part 240, a mirror 250, four wiring parts 261, four wiring parts 262, four wiring parts 263, and four wiring parts 264. The drive parts 221, the monitoring parts 222, and the wiring parts 261 to 264 will be described later with reference to FIG. 14.

The drive element 2 is configured to be point-symmetrical about a center 2a. The movable part 240 is provided at the center of the drive element 2, and rotates about a rotation axis R10 which passes through the center 2a and extends in the X-axis direction.

Drive units U11 and U12 are placed on the X-axis negative side and the X-axis positive side of the movable part 240, respectively. The drive unit U11 includes a side portion on the X-axis negative side of the fixation part 210, four vibration parts 220, two drive parts 221, two monitoring parts 222, connection parts 231 to 235, two wiring parts 261, two wiring parts 262, two wiring parts 263, and two wiring parts 264. The drive unit U12 has the same configuration as the drive unit U11, and includes a side portion on the X-axis positive side of the fixation part 210 instead of the side portion on the X-axis negative side of the fixation part 210.

The fixation part 210 is provided at the outer periphery of the drive element 2. When the drive element 2 is installed, the surface on the Z-axis negative side of the fixation part 10 is installed on an installation surface. The fixation part 210 rotatably supports the movable part 240.

Each vibration part 220 has a rectangular shape long in the Y-axis direction in a plan view. The four vibration parts 220 and the connection parts 231 to 235 which are located on the X-axis positive side or the X-axis negative side of the center 2a have a meander shape in a plan view.

Here, as shown in FIG. 13, the four vibration parts 20 aligned from a far position toward a near position with respect to the center 2a are referred to as first vibration part, second vibration part, third vibration part, and fourth vibration part in this order. At the first to fourth vibration parts located on the X-axis negative side of the center 2a, the first vibration part is connected to the fixation part 210 via the connection part 231 in the vicinity of an end portion on the Y-axis negative side thereof, the first and second vibration parts are connected to each other via the connection part 232 in the vicinity of end portions on the Y-axis positive side thereof, the second and third vibration parts are connected to each other via the connection part 233 in the vicinity of end portions on the Y-axis negative side thereof, the third and fourth vibration parts are connected to each other via the connection part 234 in the vicinity of end portions on the Y-axis positive side thereof, and the fourth vibration part is connected to the movable part 240 via the connection part 235 in the vicinity of an end portion on the Y-axis negative side thereof. The first to fourth vibration parts located on the X-axis positive side of the center 2a are also connected to the fixation part 210 and the movable part 240 while being connected to each other by the connection parts 231 to 235.

The fixation part 210 has the same lamination structure as the fixation part 10 of Embodiment 1. Each vibration part 220 has the same lamination structure as each vibration part 20 of Embodiment 1. The connection parts 231 to 235 have the lamination structures as the connection parts 31 and 32 of Embodiment 1. The movable part 240 has the same lamination structure as the movable part 40 of Embodiment 1.

The mirror 250 is placed on the surface on the Z-axis positive side of the movable part 240. The movable part 240 and the mirror 250 have a circular shape centered on the center 2a in a plan view.

A fixation layer 11 similar to that of Embodiment 1 may also be installed on the lower surface of the base layer 101 corresponding to the fixation part 210. In this case as well, a face spring part having the same thickness as the connection part 231 may be formed in a predetermined range on the fixation part 210 side from the connection position between the fixation part 210 and each connection part 231. Accordingly, the same effects as those of the face spring part 12 of Embodiment 1 are achieved.

FIG. 14 is a plan view showing configurations of a part of the fixation part 210, the first to fourth vibration parts, the connection parts 231 to 235, the two drive parts 221, the two monitoring parts 222, and the wiring parts 261 to 264 which are located on the X-axis negative side of the center 2a. Each part located on the X-axis positive side of the center 2a has the same configuration as in FIG. 14, and thus is not shown, and the description thereof is omitted.

The drive parts 221 which rotate the movable part 240 are placed on the upper surface side of the first and third vibration parts, respectively. Each drive part 221 is a so-called piezoelectric transducer. Similar to each drive part 21 of Embodiment 1, each drive part 221 includes a lower electrode 111a, a piezoelectric layer 112a (see FIG. 6D), an upper electrode 113a, and an insulating layer 121 (see FIG. 6D) which covers these layers. When a drive signal (voltage) is applied the drive part 221, the vibration part 220 on which the drive part 221 is placed is driven.

The monitoring parts 222 for monitoring the operation of the drive parts 221 are placed on the upper surface side of the second and fourth vibration parts, respectively. Similar to each monitoring part 22 of Embodiment 2, each monitoring part 222 includes a lower electrode 111b, a piezoelectric layer 112b (see FIG. 11B), an upper electrode 113b, and an insulating layer 121 (see FIG. 11B) which covers these layers.

Similar to the wiring parts 61 and 62 of Embodiment 1, the wiring parts 261 and 262 are composed of single conductive layers 131a and 131b, respectively. Similar to the wiring parts 63 and 64 of Embodiment 2, the wiring parts 263 and 264 are composed of single conductive layers 131c and 131d, respectively.

The wiring parts 261 are installed between the upper electrode 113a of the first vibration part and the fixation part 210 and between the upper electrode 113a of the first vibration part and the upper electrode 113a of the third vibration part, respectively. Each wiring part 261 is connected to each upper electrode 113a via a contact hole 121a formed in the insulating layer 121 as in FIGS. 6C and 6D. An electrode 261a having a predetermined size is formed at an end portion of the wiring part 261 located on the fixation part 10 side. The electrode 261a on the fixation part 210, the upper electrode 113a of the first vibration part, and the upper electrode 113a of the third vibration part are connected in series by the two wiring parts 261.

The wiring parts 262 are installed between an exposed portion 221a on the Y-axis negative side of the lower electrode 111a of the first vibration part and the fixation part 210 and between an exposed portion 221a on the Y-axis positive side of the lower electrode 111a of the first vibration part and an exposed portion 221a of the lower electrode 111a of the third vibration part, respectively. Each wiring part 262 is connected to each exposed portion 221a via a contact hole 121b formed in the insulating layer 121 as in FIGS. 6C and 6D. An electrode 262a having a predetermined size is formed at an end portion of the wiring part 262 located on the fixation part 10 side. The electrode 262a on the fixation part 210, the lower electrode 111a of the first vibration part, and the lower electrode 111a of the third vibration part are connected in series by the two wiring parts 262.

The wiring parts 263 are installed between the upper electrode 113b of the second vibration part and the fixation part 210 and between the upper electrode 113b of the second vibration part and the upper electrode 113b of the fourth vibration part, respectively. Each wiring part 263 is connected to each upper electrode 113b via a contact hole 121c formed in the insulating layer 121 as in FIGS. 11A and 11B. An electrode 263a having a predetermined size is formed at an end portion of the wiring part 263 located on the fixation part 10 side. The electrode 263a on the fixation part 210, the upper electrode 113b of the second vibration part, and the upper electrode 113b of the fourth vibration part are connected in series by the two wiring parts 263.

The wiring parts 264 are installed between an exposed portion 222a on the Y-axis positive side of the lower electrode 111b of the second vibration part and the fixation part 210 and between an exposed portion 222a on the Y-axis negative side of the lower electrode 111b of the second vibration part and an exposed portion 222a of the lower electrode 111b of the fourth vibration part, respectively. Each wiring part 264 is connected to each exposed portion 222a via a contact hole 121d formed in the insulating layer 121 as in FIGS. 11A and 11B. An electrode 264a having a predetermined size is formed at an end portion of the wiring part 264 located on the fixation part 10 side. The electrode 264a on the fixation part 210, the lower electrode 111b of the second vibration part, and the lower electrode 111b of the fourth vibration part are connected in series by the two wiring parts 264.

A cable (external wire) connected to an external power supply, a circuit, or the like is connected to each of the upper surfaces of the electrodes 261a, 262a, 263a, and 264a by wire bonding. Alternatively, a BGA substrate or a substrate with through-wiring, which is connected to an external power supply, a circuit, or the like, may be connected to each of the upper surfaces of the electrodes 261a, 262a, 263a, and 264a by metal bonding. When a drive signal (voltage) is applied to each of the two drive parts 221 via the cable or the substrate from the external power supply or the like, the piezoelectric layers 112a of the drive parts 221 are deformed by an inverse piezoelectric effect, and the first and third vibration parts vibrate so as to bend. When the first and third vibration parts bend by driving the drive parts 221, the second and fourth vibration parts also vibrate so as to bend. A detection signal (current or charge) generated in each of the monitoring parts 222 on the second and fourth vibration parts due to a piezoelectric effect is outputted to the external circuit via the cable or the substrate. Accordingly, the operation of the drive parts 221 can be monitored by the external circuit.

When the drive element 2 is driven, drive signals having the same phase are applied to the drive parts 221 on the two first vibration parts and the two third vibration parts such that these vibration parts vibrate in the same direction in the Z-axis direction. Accordingly, the movable part 240 and the mirror 250 rotate about the rotation axis R10, so that the direction of light incident on the mirror 250 is changed in accordance with the rotation angle of the mirror 250.

### Effects of Embodiment 3

According to Embodiment 3, the following effects are achieved.

Each wiring part 261 composed of the single conductive layer 131a which is connected to the upper electrode 113a of the drive part 221 is installed up to the fixation part 10, and each wiring part 263 composed of the single conductive layer 131c which is connected to the upper electrode 113b of the monitoring part 222 is installed up to the fixation part 10. With this configuration, since the wiring parts 261 and 263 do not include a piezoelectric layer, the same effects as the effects due to the fact that there is no piezoelectric layer at the installation positions of the above-described wiring parts 61 and 63 in Embodiments 1 and 2 are achieved.

Each wiring part 262 composed of the single conductive layer 131b which is connected to the exposed portion 221a of the lower electrode 111a of the drive part 221 is installed up to the fixation part 10, and each wiring part 264 composed of the single conductive layer 131d which is connected to the exposed portion 222a of the lower electrode 111b of the monitoring part 222 is installed up to the fixation part 10. With this configuration, since the wiring parts 262 and 264 do not include a piezoelectric layer, the same effects as the effects due to the fact that there is no piezoelectric layer at the installation positions of the above-described wiring parts 62 and 64 in Embodiments 1 and 2 are achieved.

Since there is no piezoelectric layer in any of the wiring parts 261 to 264 aligned adjacent to each other on the X-axis positive side or the X-axis negative side of the center 2a, the parasitic capacitance between these four wiring parts can be significantly reduced. Therefore, noise propagation between these four wiring parts can be suppressed, so that deterioration of the drive characteristics of the movable part 240 can be suppressed.

An end portion on the fixation part 10 side of the conductive layer 131a is widened to form the electrode 261a, and an end portion on the fixation part 10 side of the conductive layer 131b is widened to form the electrode 262a. With this configuration, since there is no piezoelectric layer at the positions of the electrodes 261a and 262a, the same effects as the effects due to the fact that there is no piezoelectric layer at the positions of the above-described electrodes 61a and 62a in Embodiment 1 are achieved.

As shown in FIG. 13, the two drive units U11 and U12 are placed with the movable part 240 interposed therebetween. Accordingly, the rotation angle of the movable part 240 can be larger than that in the case where a drive unit is placed only on one side in the X-axis direction with respect to the movable part 240. In addition, the movable part 240 can be held stably and can have high resistance to external impact.

### Modification 1 of Embodiment 3

In Embodiment 3 above, only one of the drive part 221 and the monitoring part 222 is placed on each vibration part 220, but both the drive part 221 and the monitoring part 222 may be placed thereon.

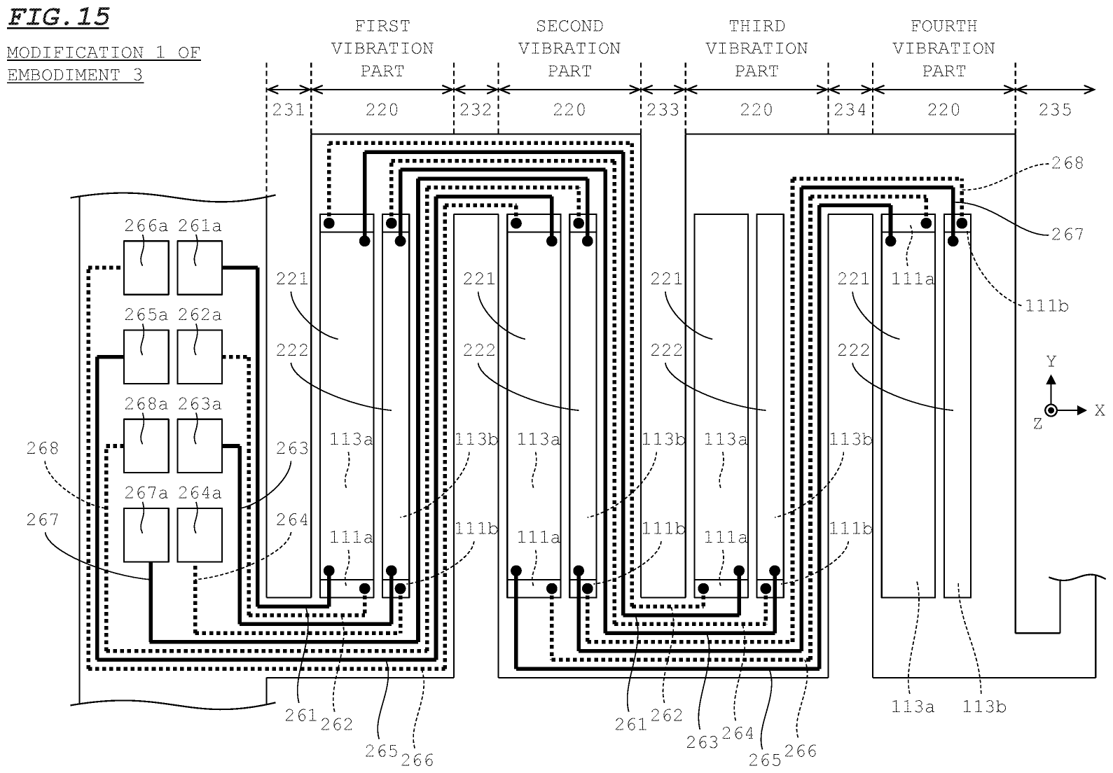

FIG. 15 is a plan view showing a configuration of a drive element 2 according to Modification 1 of Embodiment 3. In FIG. 15, for convenience, only the configuration on the X-axis negative side of the center 2a is shown as in FIG. 14.

At each vibration part 220, the drive part 221 and the monitoring part 222 have a rectangular shape long in the Y-axis direction in a plan view, and are aligned with a gap in the X-axis direction.

The electrode 261a and the upper electrodes 113a of the drive parts 221 on the first and third vibration parts are connected in series by the two wiring parts 261. The electrode 262a and the lower electrodes 111a of the drive parts 221 on the first and third vibration parts are connected in series by the two wiring parts 262. The electrode 263a and the upper electrodes 113b of the monitoring parts 222 on the first and third vibration parts are connected in series by the two wiring parts 263. The electrode 264a and the lower electrodes 111b of the monitoring parts 222 on the first and third vibration parts are connected in series by the two wiring parts 264.

An electrode 265a and the upper electrodes 113a of the drive parts 221 on the second and fourth vibration parts are connected in series by two wiring parts 265. An electrode 266a and the lower electrodes 111a of the drive parts 221 on the second and fourth vibration parts are connected in series by two wiring parts 266. An electrode 267a and the upper electrodes 113b of the monitoring parts 222 on the second and fourth vibration parts are connected in series by two wiring parts 267. An electrode 268a and the lower electrodes 111b of the monitoring parts 222 on the second and fourth vibration parts are connected in series by two wiring parts 268.

Similar to the wiring parts 61 and 62 of Embodiment 1, the wiring parts 265 and 266 are composed of single conductive layers 131a and 131b, respectively. Similar to the wiring parts 63 and 64 of Embodiment 2, the wiring parts 267 and 268 are composed of single conductive layers 131c and 131d, respectively.

In Modification 1 of Embodiment 3 as well, since the wiring parts 261 to 268 do not include a piezoelectric layer, the same effects as those of Embodiment 3 are achieved.

Furthermore, compared to Embodiment 3, both the drive part 221 and the monitoring part 222 are placed on each vibration part 220, so that highly accurate drive characteristics can be achieved.

### Modification 2 of Embodiment 3

In Modification 1 of Embodiment 3, the wiring parts 261 to 268 are installed up to the fixation part 10 so as to bypass the regions of the monitoring parts 222 as shown in FIG. 15, but may be overlaid above the monitoring parts 222.

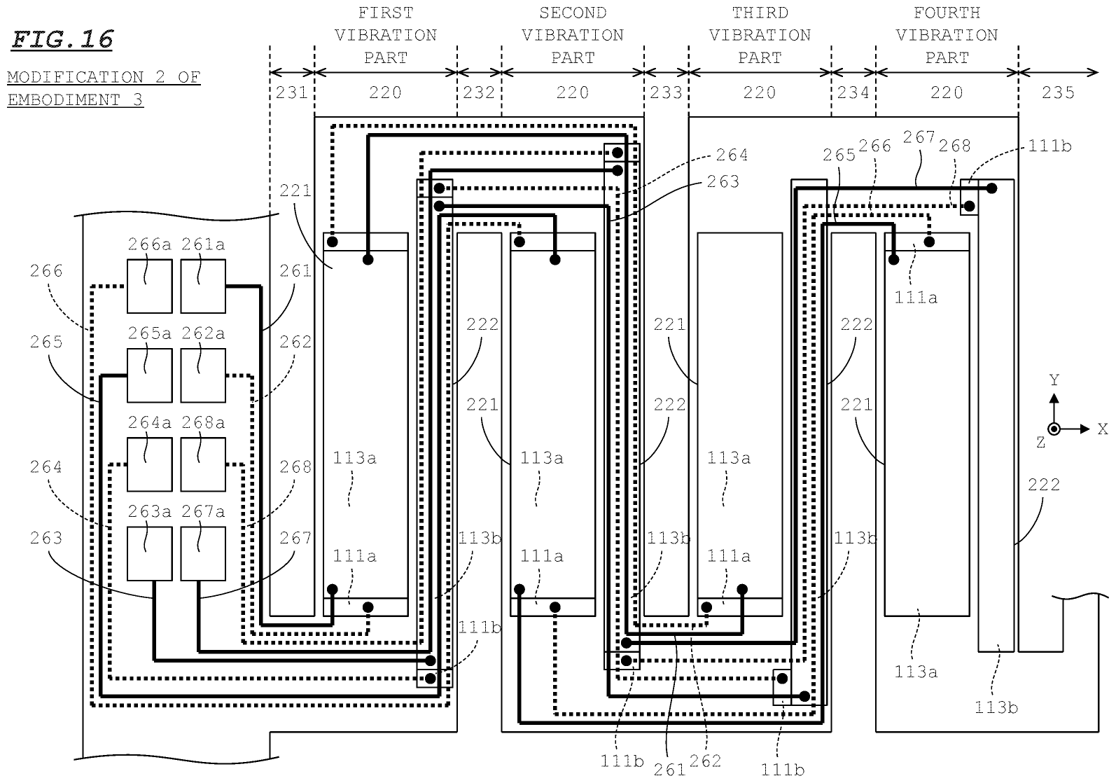

FIG. 16 is a plan view showing a configuration of a drive element 2 according to Modification 2 of Embodiment 3. In FIG. 16, for convenience, only the configuration on the X-axis negative side of the center 2a is shown as in FIG. 15.

An insulating layer 121 is formed on the upper surface side of the drive parts 221 and the monitoring parts 222 as in the configuration shown in FIGS. 12B and 12D.

The wiring parts 265 to 268 extending from the drive part 221 and the monitoring part 222 on the second vibration part to the fixation part 10 are formed so as to traverse the upper surface of the insulating layer 121 on the monitoring part 222 on the first vibration part. The wiring parts 261 to 264 extending from the drive part 221 and the monitoring part 222 on the third vibration part to the first vibration part are formed so as to traverse the upper surface of the insulating layer 121 on the monitoring part 222 on the second vibration part. The wiring parts 265 to 268 extending from the drive part 221 and the monitoring part 222 on the fourth vibration part to the second vibration part are formed so as to traverse the upper surface of the insulating layer 121 on the monitoring part 222 on the third vibration part.

When the wiring parts 261 to 268 are formed so as to traverse the upper surfaces of the insulating layers 121 on the monitoring parts 222 as described above, the wiring parts 261 to 268 can be efficiently placed, so that the area of each drive part 221 can be increased, thereby increasing a driving force.

### Other Modifications

In Embodiment 3 above, the drive parts 221 are placed on the first and third vibration parts, and the monitoring parts 222 are placed on the second and fourth vibration parts, but the drive parts 221 may be placed on all the first to fourth vibration parts.

In this case, when the drive element 2 is driven, drive signals having the same phase are applied to the drive parts 221 on the two first vibration parts and the two third vibration parts such that these vibration parts vibrate in the same direction in the Z-axis direction, and drive signals having the same phase are applied to the drive parts 221 on the two second vibration parts and the two fourth vibration parts such that these vibration parts vibrate in the same direction in the Z-axis direction. In addition, drive signals having opposite phases are applied to the drive parts 221 on the first and third vibration parts and the drive parts 221 on the second and fourth vibration parts such that the first and third vibration parts and the second and fourth vibration parts vibrate in opposite directions in the Z-axis direction.

A monitoring part 222 may be placed on each of the first and third vibration parts, and a drive part 221 may be placed on each of the second and fourth vibration parts.

In Embodiment 3 above, in the case where it is not necessary to monitor the operation of each drive part 221, the monitoring parts 222 on the second and fourth vibration parts and the wiring parts 263 and 264 may be omitted. Similarly, in Embodiment 3 above, a drive part 221 may be placed on each of the second and fourth vibration parts, and the drive parts 221 on the first and third vibration parts and the wiring parts 261 and 262 may be omitted. In Modifications 1 and 2 of Embodiment 3 above, the drive parts 221 and the monitoring parts 222 on the first to fourth vibration parts may be omitted as appropriate. However, if the parasitic capacitance of each wiring part is a problem, a monitoring part 222 may be provided only on the first vibration part.

In Embodiment 1 above, the placement of the drive parts 21 is not limited to the layout shown in FIG. 1. For example, each drive part 21 may be provided only near the distal end of the vibration part 20. In Embodiment 2 and the modification of Embodiment 2 above, the placement of the drive parts 21 and the monitoring parts 22 is not limited to the layouts shown in FIGS. 10, 12A, and 12C. For example, each monitoring part 22 may be provided near the distal end of the vibration part 20, and each drive part 21 may be provided near the base of the vibration part 20 (the vibration part 20 in a region near the connection parts 31 and 32). In Embodiment 2 and the modification of Embodiment 2 above, even in the case where the placement of the drive parts 21 and the monitoring parts 22 is changed, the wiring parts 61 and 62 may be placed so as to traverse the upper side of the monitoring part 22, and the wiring parts 63 and 64 may be placed so as to traverse the upper side of the drive part 21, as in the case shown in FIGS. 12A and 12C.

In Embodiments 1 to 3 above, wiring parts are provided individually for the lower electrodes 111a and 111b. However, instead of the lower electrodes 111a and 111b, lower electrodes may be provided so as to extend over the regions of the fixation part and all the vibration parts. In this case, the lower electrodes are connected to an external circuit at the fixation part, and are connected to a ground at the external circuit.

In Embodiments 1 to 3 above, the conductive layers 131a, 131b, 131c, and 131d are made of gold (Au), but may be made of another material having conductivity. In addition, each of the conductive layers 131a, 131b, 131c, and 131d only needs to be a single layer, and is not limited to being made of only a single material. The conductive layers 131a, 131b, 131c, and 131d may be made of a mixture of multiple materials.

In Embodiments 1 to 3 above, the lower electrodes 111a and 111b are made of platinum (Pt), but may be made of another material having conductivity. The piezoelectric layers 112a and 112b are made of PZT, but may be made of another material having a piezoelectric effect. The upper electrodes 113a and 113b are made of gold (Au), but may be made of another material having conductivity.

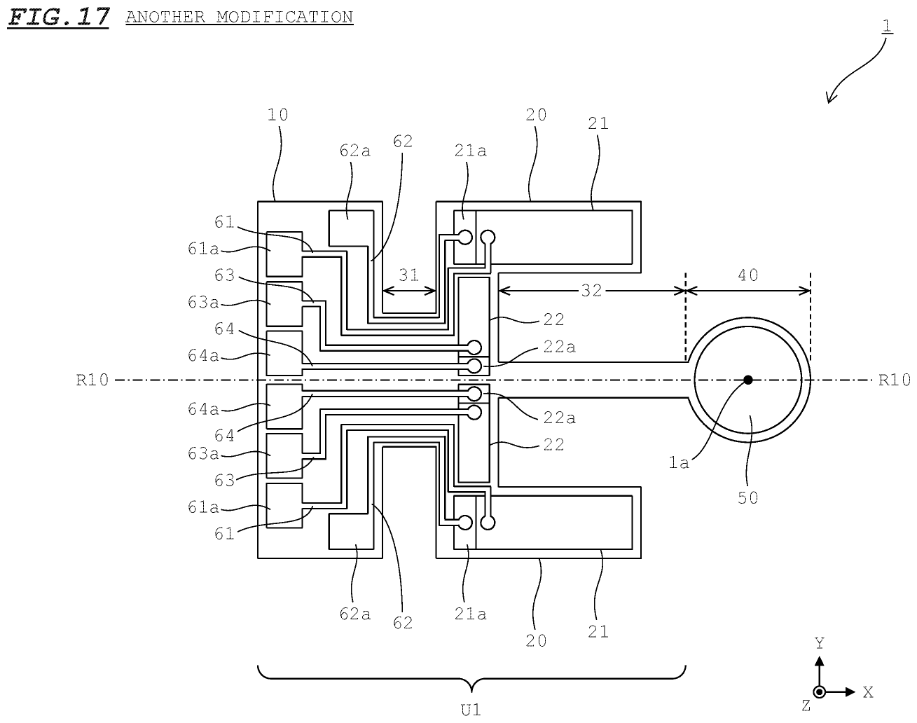

In Embodiments 1 and 2 above, as shown in FIGS. 1 and 10, the two drive units U1 and U2 are placed with the movable part 40 interposed therebetween, but any one of the two drive units U1 and U2 may be omitted. For example, as shown in FIG. 17, the drive unit U2 may be omitted, and the drive element 1 may include one drive unit U1. Similarly, in Embodiment 3 above, as shown in FIG. 13, the two drive units U11 and U12 are placed with the movable part 240 interposed therebetween, but any one of the two drive units U11 and U12 may be omitted.

In addition to the above, various modifications can be made as appropriate to the embodiments of the present invention, without departing from the scope of the technological idea defined by the claims.

What is claimed is:

1. A drive element for rotating a movable part about a rotation axis, the drive element comprising:
a fixation part rotatably supporting the movable part; and
a drive part configured to rotate the movable part, wherein
the drive part includes
a piezoelectric layer,
an upper electrode and a lower electrode placed with the piezoelectric layer interposed therebetween, and
an insulating layer covering the piezoelectric layer, the upper electrode, and the lower electrode, and
a wiring part composed of a single conductive layer connected to the upper electrode via a contact hole formed in the insulating layer is installed up to the fixation part.

2. The drive element according to claim 1, wherein
the lower electrode includes an exposed portion on which the piezoelectric layer and the upper electrode are not overlaid, and
another wiring part composed of a single conductive layer connected to the exposed portion via another contact hole formed in the insulating layer is installed up to the fixation part.

3. The drive element according to claim 1, further comprising a connection part connecting the fixation part and a vibration part on which the drive part is placed, wherein
a face spring part having the same thickness as the connection part is formed in a predetermined range on the fixation part side from a connection position between the fixation part and the connection part.

4. The drive element according to claim 1, wherein an end portion on the fixation part side of the conductive layer is widened to form an electrode.

5. The drive element according to claim 1, further comprising a monitoring part for monitoring operation of the drive part, wherein
the monitoring part includes
a piezoelectric layer,
an upper electrode and a lower electrode placed with the piezoelectric layer interposed therebetween, and
an insulating layer covering the piezoelectric layer, the upper electrode, and the lower electrode, and
a wiring part composed of a single conductive layer connected to the upper electrode via a contact hole formed in the insulating layer of the monitoring part is installed up to the fixation part.

6. The drive element according to claim 5, wherein
the lower electrode of the monitoring part includes an exposed portion on which the piezoelectric layer and the upper electrode of the monitoring part are not overlaid, and
another wiring part composed of a single conductive layer connected to the exposed portion of the monitoring part via another contact hole formed in the insulating layer of the monitoring part is installed up to the fixation part.

7. The drive element according to claim 5, wherein the wiring part connected to the drive part is formed so as to traverse an upper surface of the insulating layer of the monitoring part.

8. The drive element according to claim 5, wherein the wiring part connected to the monitoring part is formed so as to traverse an upper surface of the insulating layer of the drive part.

9. The drive element according to claim 1, wherein widths in a plane direction of the stacked lower electrode, piezoelectric layer, and upper electrode are smaller in this order.

10. The drive element according to claim 1, wherein the insulating layer is made of a material having a low Young's modulus.

11. The drive element according to claim 1, wherein the drive part is placed on a vibration part having a tuning fork shape.

12. The drive element according to claim 1, wherein the drive part is placed on a vibration part having a meander shape.

13. The drive element according to claim 1, wherein two drive units each including the fixation part, the drive part, and the wiring part are placed with the movable part interposed therebetween.

14. The drive element according to claim 1, wherein a mirror is placed on the movable part.
